(19) United States
(12) Patent Application Publication
(10) Pub. No.: US 2014/0262472 A1
(43) Pub. Date: Sep. 18, 2014

(54) INTEGRATED GROUNDED GROMMET

(71) Applicants: Howard Lind, Porter Ranch, CA (US); John Palahnuk, Valencia, CA (US)

(72) Inventors: Howard Lind, Porter Ranch, CA (US); John Palahnuk, Valencia, CA (US)

(21) Appl. No.: 13/827,166

(22) Filed: Mar. 14, 2013

(51) Int. Cl. H05K 9/00; H05K 13/00

(52) U.S. Cl. CPC H05K 9/00; H05K 13/00
USPC 174/360; 29/825; 29/33 R

(57) ABSTRACT

The embodiments disclose an integrated grounded grommet for anchoring a cable using a bulkhead opening, including a customized grommet mechanically bonded onto a cable creating a pressure seal, a customized grommet extended boss insertion guiding feature, a grounding path electrically bonded through the grommet to a cable shield, and a cable protection against EMI/RFI using the grounding path from the cable shield to a bulk head.

### BACKGROUND

Devices to hold a cable in place while passing through an opening have traditionally been a separate stand-alone piece. The traditional grommet is pulled over the cable and fitted into the opening. Some grommets are used as a strain relief method where a cable may be strung over a long distance. The separate stand-alone pieces do not interact with the cable in terms of grounding or shielding. Typical traditional grommets are used in in-line straight cable runs or only change direction in a 90 degree elbow configuration.

### BRIEF DESCRIPTION OF THE DRAWINGS

FIG. 1 shows a block diagram of an overview of an integrated grounded grommet of one embodiment.

FIG. 2A shows a block diagram of an overview flow chart of an integrated grounded grommet of one embodiment.

FIG. 2B shows a block diagram of a continuation of an overview flow chart of an integrated grounded grommet of one embodiment.

FIG. 3A shows for illustrative purposes only an example of a first shape of an in-line integrated grounded grommet of one embodiment.

FIG. 3B shows for illustrative purposes only an example of a second shape of an in-line integrated grounded grommet of one embodiment.

FIG. 3C shows for illustrative purposes only an example of a third shape of a 45 degree directional changing integrated grounded grommet of one embodiment.

FIG. 4A shows for illustrative purposes only an example of a fourth shape of a 90 degree directional changing integrated grounded grommet top left rear prospective view of one embodiment.

FIG. 4B shows for illustrative purposes only an example of a fourth shape of a 90 degree directional changing integrated grounded grommet bottom right front prospective view of one embodiment.

FIG. 5A shows for illustrative purposes only an example of a cable shielding beneath the jacket and a first grounding path conductive material woven around the shielding of one embodiment.

FIG. 5B shows for illustrative purposes only an example of a multi-conductor cable shielding beneath the jacketing and a second grounding path conductive material compressed against the shielding materials of one embodiment.

FIG. 5C shows for illustrative purposes only an example of a fourth shape of a 90 degree directional changing integrated grounded grommet right side view of one embodiment.

FIG. 5D shows for illustrative purposes only an example of a cross section of the fourth shape of a 90 degree directional changing integrated grounded grommet with a first grounding path conductive material woven around the shielding of one embodiment.

FIG. 5E shows for illustrative purposes only an example of a cross section detailed enlargement of a first grounding path conductive material woven around the shielding embedded in a customized grommet extended boss insertion guiding feature of one embodiment.

FIG. 6A shows for illustrative purposes only an example of an over-molded hard-shell and integrated grounded grommet of one embodiment.

FIG. 6B shows for illustrative purposes only an example of an over-molded hard-shell attached to an integrated grounded grommet of one embodiment.

### DETAILED DESCRIPTION OF THE INVENTION

In a following description, reference is made to the accompanying drawings, which form a part hereof, and in which is shown by way of illustration a specific example in which the invention may be practiced. It is to be understood that other embodiments may be utilized and structural changes may be made without departing from the scope of the present invention.

### General Overview:

It should be noted that the descriptions that follow, for example, in terms of an integrated grounded grommet is described for illustrative purposes and the underlying system can apply to any number and multiple types grommets. In one embodiment of the present invention, the integrated grounded grommet can be configured using an arrow shaped extended boss shape that locks into a bulkhead. The integrated grounded grommet can be configured to include a specialized silicone that bonds to a cable jacket and can be configured to include creation of a pressure seal using the present invention.

FIG. 1 shows a block diagram of an overview of an integrated grounded grommet of one embodiment. FIG. 1 shows an integrated grounded grommet used for anchoring a cable to a bulkhead 100. Contamination can enter a cable more easily when passing through a bulkhead due to cracks or breaks in the cable jacket caused by stress related conditions and changes in direction. Prevention of contamination corroding conductors or causing conductor failures can be accomplished using a customized grommet mechanically bonded onto a cable creating a pressure seal 110. The pressure seal prevents contaminates from entering the cable.

Stress on the cable frequently occurs when pushing a cable through a separate grommet or when inserting the separate grommet with the cable inserted into a bulkhead opening. The integrated grounded grommet used for anchoring a cable to a bulkhead 100 includes a customized grommet extended boss insertion guiding feature 120. The customized grommet extended boss insertion guiding feature 120 is integrated into the grommet which is integrated onto the cable. These integrated features prevent potential stress on the cable when inserting the customized grommet extended boss insertion guiding feature 120 into a bulkhead opening of one embodiment.

The integrated grounded grommet used for anchoring a cable to a bulkhead 100 includes a grounding path electrically bonded through the grommet to a cable shield 130. The grounding path prevents for example a static charge from building up along the cable route which could ultimately reach the electrical or electronic equipment to which the cable is connected. Bonding to the cable shield enables a cable protection against EMI/RFI using the grounding path from the cable shield to a bulk head 140. Protection against EMI/RFI reduces for example radio frequency interference (RFI) in communication conductors or power surges that could occur when a cable is exposed to electro-magnetic interference (EMI) of one embodiment.

### DETAILED DESCRIPTION

### Mechanical Bonding:

FIG. 2A shows a block diagram of an overview flow chart of an integrated grounded grommet of one embodiment. FIG. 2A shows an integrated grounded grommet 200 used for anchoring a cable 202 to a bulkhead. The integrated grounded grommet 200 includes features described in FIG. 2B. A bulkhead opening 206 includes openings in typical bulk head walls, thin panels or tubes 210. The bulkhead includes materials for example metal, plastic or other rigid material 214 of one embodiment.

A customized grommet mechanically bonded onto a cable creating a pressure seal 110 can be fabricated using one or more specialized silicone that bonds to the cable jacket 218. The one or more specialized silicone is compression molded into various shapes and sizes 220. The compression molding is customized for creating a pressure seal 224. The pressure seal created has a capacity up to 45 psi of h20, o2 and other gases 228.

The cable running through the grommet 230 can enter and exit the grommet at numerous angles 234. The customized shapes enable the cable to change direction within the grommet 238. The custom shapes and sizes of the grommet can include allowances for an over-molded hard-shell for increased mechanical strength 240. Other features of the customized shapes are described in FIG. 2B of one embodiment.

### Electrical Bonding:

FIG. 2B shows a block diagram of a continuation of an overview flow chart of an integrated grounded grommet of one embodiment. FIG. 2B shows features directed from FIG. 2A that are used in the anchoring a cable 202 of FIG. 2A to a bulkhead. A conductive material 250 is embedded in the grommet 254 and electrically bonded to the cable 258. The conductive material 250 creates a direct physical and electrical contact with a cable shielding and bulkhead 260. The electrical bonding creates a solid low resistance grounding path 270 with a volume resistivity equal to 0.004 ohms/cm grounding to a bulkhead 274. The electrical bonding to the cable shielding creates a cable protection against EMI/RFI 280 through a 20 mhz to 10 ghz range 284 when inserted into the bulkhead opening 206 of FIG. 2A as described in FIG. 2A of one embodiment.

The one or more specialized silicone that bonds to the cable jacket 218 of FIG. 2A as described in FIG. 2A is used to create a customized compression molded grommet extended boss insertion guiding feature 120. The grommet extended boss insertion guiding feature is used when inserting the grommet into the bulkhead opening 206 of FIG. 2A as described in FIG. 2A. The grommet extended boss insertion guiding feature can include an arrow shape end 290. The arrow shape end 290 locks into place when pushed through the bulkhead opening 294 as described in FIG. 2A of one embodiment. In the following illustrations in FIG. 3A through FIG. 6B cables are shown terminated a short distance before entering and after exiting the integrated grounded grommet 200 of FIG. 2A. This short termination of the cables is for ease of viewing the cable orientations and does not reflect the true length or subsequent routing of the cables. The cable may be of any length and originate or terminate from a device to which it is connected or from another integrated grounded grommet 200 of FIG. 2A not shown in the illustrations. Bulkheads if shown are illustrated as straight sections for ease of illustration. A bulkhead can be made from metal, plastic or other rigid material and may be of a shape consistent with typical bulkhead walls, thin panels or tubes. While the illustrations are oriented horizontally or vertically the integrated grounded grommet 200 of FIG. 2A can be inserted into a bulkhead opening 206 of FIG. 2A oriented in any direction or orientation. No limitations should be inferred or attached to the present invention by the illustrative limitations.

### First Shape Grommet:

FIG. 3A shows for illustrative purposes only an example of a first shape of an in-line integrated grounded grommet of one embodiment. FIG. 3A shows an in-line multi-conductor cable 300 running through a first shape in-line integrated grounded grommet 310. The first shape in-line integrated grounded grommet 310 includes a first shape in-line extended boss insertion guiding feature 320. The in-line multi-conductor cable 300 remains in its in-line orientation as it passes through a bulkhead 325. The first shape in-line extended boss insertion guiding feature 320 is inserted into a bulkhead opening 206 of FIG. 2A and supports the in-line multi-conductor cable 300 in its in-line orientation of one embodiment.

### Second Shape Grommet:

FIG. 3B shows for illustrative purposes only an example of a second shape of an in-line integrated grounded grommet of one embodiment. FIG. 3B shows the in-line multi-conductor cable 300 maintaining an in-line routing through a second shape in-line integrated grounded grommet 330. The second shape in-line integrated grounded grommet 330 includes a second shape stand-off extended boss insertion guiding feature 340. The second shape stand-off extended boss insertion guiding feature 340 enables insertion into a bulkhead opening 206 of FIG. 2A to support the in-line multi-conductor cable 300 along a route parallel to the bulkhead 325 of one embodiment.

### Third Shape 45 Degree Grommet:

FIG. 3C shows for illustrative purposes only an example of a third shape of a 45 degree directional changing integrated grounded grommet of one embodiment. FIG. 3C shows the in-line multi-conductor cable 300 entering a third shape 45 degree directional changing integrated grounded grommet 350. The third shape 45 degree directional changing integrated grounded grommet 350 includes a third shape 45 degree extended boss insertion guiding feature 360. The compression process and apparatus used to shape the third shape 45 degree directional changing integrated grounded grommet 350 and third shape 45 degree extended boss insertion guiding feature 360 includes a process to change the direction of the in-line multi-conductor cable 300 to any predetermined angle as it passes through the bulkhead 325. The third shape 45 degree directional changing integrated grounded grommet 350 is shaped and processed to result in a 45 degree angled multi-conductor cable 370 exiting the third shape 45 degree extended boss insertion guiding feature 360. The one or more specialized silicone that bonds to the cable jacket 218 of FIG. 2A and is used for creating a pressure seal 224 of FIG. 2A maintains the pressure seal through the 45 degree direction change and insertion into the bulkhead opening 206 of FIG. 2A of one embodiment.

### Fourth Shape 90 Degree Grommet:

FIG. 4A shows for illustrative purposes only an example of a fourth shape of a 90 degree directional changing integrated grounded grommet top left rear prospective view of one embodiment. FIG. 4A shows a fourth shape 90 degree directional changing integrated grounded grommet 400 including a fourth shape arrow shape ended extended boss insertion guiding feature 410. The fourth shape 90 degree directional changing integrated grounded grommet 400 enables the in-line multi-conductor cable 300 to change direction to a 90 degree angled multi-conductor cable 430 of one embodiment.

### Arrow Shape Ended Extended Boss:

FIG. 4B shows for illustrative purposes only an example of a fourth shape of a 90 degree directional changing integrated grounded grommet bottom right front prospective view of one embodiment. FIG. 4B shows the fourth shape 90 degree directional changing integrated grounded grommet 400 and the fourth shape arrow shape ended extended boss insertion guiding feature 410. The in-line multi-conductor cable 300 and running through the fourth shape 90 degree directional changing integrated grounded grommet 400 changes direction within the grommet. The exiting 90 degree angled multi-conductor cable 430 is supported by the fourth shape arrow shape ended extended boss insertion guiding feature 410 when inserted into a bulkhead opening 206 of FIG. 2A. The fourth shape 90 degree directional changing integrated grounded grommet 400 includes a curved bulkhead shape 440 for use with tube bulkheads. The curved fourth shape arrow shape ended extended boss insertion guiding feature 410 easily conforms to the tube bulkhead opening and locks into position when inserted by use of the arrow shaped end flanges of one embodiment.

### First Grounding Path Conductive Material:

FIG. 5A shows for illustrative purposes only an example of a cable shielding beneath the jacket and a first grounding path conductive material woven around the shielding of one embodiment. FIG. 5A shows a conductor cable 500 where the cable jacket 510 has been stripped away. The section where the cable jacket 510 has been stripped away reveals one type of cable conductor 530 shielding 520. The shielding 520 is installed over the conductor 535 insulation 530. A first grounding path conductive material 540 woven around the shielding 520 creates a solid low resistance grounding path 270 of FIG. 2B embedded in the grommet 254 of FIG. 2B of one embodiment.

### Second Grounding Path Conductive Material:

FIG. 5B shows for illustrative purposes only an example of a multi-conductor cable shielding beneath the jacketing and a second grounding path conductive material compressed against the shielding materials of one embodiment. FIG. 5B shows the multi-conductor cable 300 with the jacketing 510 stripped away revealing the cable shielding 520 on each of the conductors. A second grounding path conductive material 545 is compressed against the shielding 520 materials and exposed conductor insulation 530. The second grounding path conductive material 545 includes a wire mesh material that can be slipped or wrapped over the shielding 520. The compressed second grounding path conductive material 545 creates a solid low resistance grounding path 270 of FIG. 2B embedded in the grommet 254 of FIG. 2B of one embodiment.

The grounding path conductive material includes mixing into the grommet filler material metal flakes or other conductive materials. The mixed grounding path conductive material contacts the shielding 520 and creates a solid low resistance grounding path 270 of FIG. 2B embedded in the grommet. When the grommet is molded around the exposed shielding 520 materials an embedded direct physical and electrical contact with a cable shielding and bulkhead 260 of FIG. 2B is created of one embodiment.

### Bulkhead:

FIG. 5C shows for illustrative purposes only an example of a fourth shape of a 90 degree directional changing integrated grounded grommet right side view of one embodiment. FIG. 5C shows the fourth shape 90 degree directional changing integrated grounded grommet 400 including the fourth shape arrow shape ended extended boss insertion guiding feature 410. The in-line multi-conductor cable 300 changes direction to become the 90 degree angled multi-conductor cable 430. The fourth shape arrow shape ended extended boss insertion guiding feature 410 inserted into the bulkhead 325 which for example can be metal. The cross-section orientation lines 510 indicate the section of the fourth shape 90 degree directional changing integrated grounded grommet 400 shown in FIG. 5D of one embodiment.

### Grommet Cross-Section:

FIG. 5D shows for illustrative purposes only an example of a cross section of the fourth shape of a 90 degree directional changing integrated grounded grommet with a first grounding path conductive material woven around the shielding of one embodiment. FIG. 5D shows a cross section of the fourth shape 90 degree directional changing integrated grounded grommet 400 illustrating the insertion point of the fourth shape arrow shape ended extended boss insertion guiding feature 410. The in-line multi-conductor cable 300 enters the end of the fourth shape 90 degree directional changing integrated grounded grommet 400. The in-line multi-conductor cable 300 changes direction within the grommet to become the 90 degree angled multi-conductor cable 430. The fourth shape arrow shape ended extended boss insertion guiding feature 410 is shown locked into position in the bulkhead 325. The cross section of the multi-conductor cable includes a conductor 535 and shield 520 encased by the cable jacket 510. The first grounding path conductive material 540 woven around the shielding 520 creates a solid low resistance grounding path 270 of FIG. 2B embedded in the grommet 254 of FIG. 2B to the bulkhead 325. A detail area 570 indicates the area shown enlarged in FIG. 5C of one embodiment.

### Grounding Path:

FIG. 5E shows for illustrative purposes only an example of a cross section detailed enlargement of a first grounding path conductive material woven around the shielding embedded in a customized grommet extended boss insertion guiding feature of one embodiment. FIG. 5E shows the detail area 570 including portions of the fourth shape 90 degree directional changing integrated grounded grommet 400 and fourth shape arrow shape ended extended boss insertion guiding feature 410 locked into position. The in-line multi-conductor cable 300 is partially shown in the direction changing bend to the 90 degree angled multi-conductor cable 430. The bulkhead 325 includes the bulkhead opening 206 of FIG. 2A. The conductor 535 is shown centered in the multi-conductor cable. FIG. 5E shows the embedded first grounding path conductive material 540 is woven around the shielding 520 where the cable jacket has been stripped away of one embodiment.

A grounding path conductive material bus 580 is shown embedded in the fourth shape arrow shape ended extended boss insertion guiding feature 410. The grounding path conductive material bus 580 at one end is in direct physical and electrical contact with the shield 520 after penetrating the cable jacket 510. The opposite end of the embedded grounding path conductive material 580 is exposed outside the fourth shape arrow shape ended extended boss insertion guiding feature 410. The grounding path conductive material bus 580 makes contact with the bulkhead 325 when inserted. The first grounding path conductive material 540 is connected to a grounding path conductive material bus 580 embedded in the fourth shape arrow shape ended extended boss insertion guiding feature 410. The grounding path conductive material bus 580 contact with the bulkhead 325 completes the electrical bonding of the shield 520 and the first grounding path conductive material 540 to the bulkhead 325 of one embodiment.

The direct physical and electrical contact between the shield 520 and the bulkhead 325 using the embedded first grounding path conductive material 540 and grounding path conductive material bus 580 creates the electrical bonding used for a solid low resistance grounding path 270 of FIG. 2B with a volume resistivity equal to 0.004 ohms/cm grounding to a bulkhead 274 of FIG. 2B. The electrical bonding creates a cable protection against EMI/RFI 280 of FIG. 2B through a 20 mhz to 10 ghz range 284 of FIG. 2B of one embodiment.

### Over-Molded Grommet:

FIG. 6A shows for illustrative purposes only an example of an over-molded hard-shell and integrated grounded grommet of one embodiment. FIG. 6A shows the in-line multi-conductor cable 300 running through an over-molded 90 degree directional changing integrated grounded grommet 620 and changing direction within the grommet to become the 90 degree angled multi-conductor cable 430. The over-molded 90 degree directional changing integrated grounded grommet 620 includes two or more hard-shell receiving notch 630 features. The hard-shell receiving notch 630 features enable attachment of an over-molded hard-shell 600. The over-molded hard-shell 600 includes two or more hard-shell attachment flange 610 features used for attaching the over-molded hard-shell 600 to the over-molded 90 degree directional changing integrated grounded grommet 620 to increased mechanical strength. The over-molded 90 degree directional changing integrated grounded grommet 620 is made of a soft material where the over-molded hard-shell 600 is made of a more rigid material. The increased mechanical strength of the over-molded hard-shell 600 provides greater protection of the grommet in circumstances where the grommet may be exposed to impacts of one embodiment.

### Over-Molded Hard-Shell:

FIG. 6B shows for illustrative purposes only an example of an over-molded hard-shell attached to an integrated grounded grommet of one embodiment. FIG. 6B shows the in-line multi-conductor cable 300 and 90 degree angled multi-conductor cable 430 positioned running through the over-molded 90 degree directional changing integrated grounded grommet 620. The over-molded hard-shell 600 is shown attached to the over-molded 90 degree directional changing integrated grounded grommet 620 using the hard-shell receiving notch 630 and hard-shell attachment flange 610 of one embodiment.

The foregoing has described the principles, embodiments and modes of operation of the present invention. However, the invention should not be construed as being limited to the particular embodiments discussed. The above described embodiments should be regarded as illustrative rather than restrictive, and it should be appreciated that variations may be made in those embodiments by workers skilled in the art without departing from the scope of the present invention as defined by the following claims.

What is claimed is:

1. An integrated grounded grommet for anchoring a cable using a bulkhead opening, comprising:
a customized grommet mechanically bonded onto a cable creating a pressure seal;
a customized grommet extended boss insertion guiding feature;
a grounding path electrically bonded through the grommet to a cable shield; and;
a cable protection against EMI/RFI using the grounding path from the cable shield to a bulk head.

2. The integrated grounded grommet of claim 1, wherein the grommet is configured to be inserted into a bulkhead made from metal, plastic or other rigid material found in typical bulk head walls, thin panels or tubes.

3. The integrated grounded grommet of claim 1, wherein the grommet mechanical bonding includes using a specialized silicone that bonds to the cable jacket creating a pressure seal up to 45 PSI of H₂0, O² and other gases.

4. The integrated grounded grommet of claim 1, wherein the grounding path makes direct physical and electrical contact with the shields running though the cable to the bulkhead and is configured to create a solid low resistance grounding path with a volume resistivity equal to 0.004 ohms/cm grounding to a bulkhead and configured to protect the cable against EMI/RFI through a 20 Mhz to 10 Ghz range.

5. The integrated grounded grommet of claim 1, wherein the cable can enter and exit the grommet in numerous angles and change direction within the grommet.

6. The integrated grounded grommet of claim 1, wherein grommet is configured to include an over-molded hard-shell for increased mechanical strength.

7. The integrated grounded grommet of claim 1, wherein the grommet extended boss insertion guiding feature is configured to include an arrow shape, so that it locks into place when pushed through the bulkhead opening.

8. The integrated grounded grommet of claim 1, wherein the grommet is soft and is configured for compression sealed applications.

9. The integrated grounded grommet of claim 1, wherein the grommet can be molded into various shapes and sizes.

10. The integrated grounded grommet of claim 1, wherein the cable running through the grommet can enter and exit the grommet is numerous angles and change direction within the grommet.

11. A method of fabricating an integrated grounded grommet, comprising:
compressing a customized grommet onto a cable using one or more specialized silicone material that mechanically bonds to a cable jacket;
molding an integrated grommet extended boss insertion feature for use in guiding the grommet through an opening in a bulkhead;
embedding a conductive material in the grommet to make a direct physical and electrical contact with a cable shielding feature through the grommet to the bulkhead; and;
configuring the customized grommet to accept an over-molded hard-shell for increased mechanical strength.

12. The method of claim 11, wherein the customized grommet can be compressed into various shapes and sizes configured to create a pressure seal up to 45 PSI of H₂0, O² and other gases.

13. The method of claim 11, wherein the integrated grommet extended boss insertion feature is configured to include an arrow shape, so that it locks into place when pushed through the opening in a bulkhead.

14. The method of claim 11, wherein the cable running through the grommet can enter and exit the grommet is numerous angles and change direction within the grommet.

15. The method of claim 11, wherein embedded conductive material is configured to create a solid low resistance grounding path with a volume resistivity equal to 0.004 ohms/cm grounding to a bulkhead and configured to protect the cable against EMI/RFI through a 20 Mhz to 10 Ghz range.

16. An apparatus for fabricating an integrated grounded grommet, comprising:
a means of compressing a customized grommet onto a cable using one or more specialized silicone materials that mechanically bonds to a cable jacket;
a means of molding an integrated grommet extended boss insertion feature for use in guiding the grommet through an opening in a bulkhead;
a means of embedding a conductive material in the grommet to make a direct physical and electrical contact with a cable shielding feature through the grommet to the bulkhead; and;
a means of configuring the customized grommet to accept an over-molded hard-shell for increased mechanical strength.

17. The apparatus of claim 11, further comprising means for compressing the one or more specialized silicone materials into various shapes and sizes to create a pressure seal up to 45 PSI of H₂0, O² and other gases against the cable jacket including a cable with one or more conductors and other components configured as a flat cable or other grouping shape.

18. The apparatus of claim 11, further comprising means for molding the integrated grommet extended boss insertion feature to include an arrow shape, so that it locks into place when pushed through the opening in a bulkhead.

19. The apparatus of claim 11, further comprising means for custom shaping the grommet to enable the cable running through the grommet to enter and exit the grommet is numerous angles and change direction within the grommet.

20. The apparatus of claim 11, further comprising means for embedding the conductive material in the grommet wherein the direct physical and electrical contact with the cable shielding feature creates a solid low resistance grounding path with a volume resistivity equal to 0.004 ohms/cm grounding to the bulkhead and protects the cable against EMI/RFI through a 20 Mhz to 10 Ghz range.
